(19) United States
(12) Patent Application Publication
(10) Pub. No.: US 2026/0320241 A1
(43) Pub. Date: Oct. 15, 2026

(54) SYSTEM AND METHOD FOR MACHINE LEARNING-ACCELERATED GRID LOAD INTERCONNECTIONS

(71) Applicant: GE Vernova Electrification Software Holdings LLC, Cambridge, MA (US)

(72) Inventors: Nurali VIRANI, Schenectady, NY (US); Jesse GANTZ, Woodinville, WA (US); Avnaesh JAYANTILAL, Woodinville, WA (US); Wajid MUNEER, Whitby (CA); Michael De PAOLIS, Toronto (CA); Zhanpan ZHANG, Niskayuna, NY (US); Yuling WANG, Niskayuna, NY (US); Atinuke ADEMOLA-IDOWU, Niskayuna, NY (US); Reetam Sen BISWAS, Niskayuna, NY (US)

(21) Appl. No.: 19/629,189

(22) Filed: Mar. 26, 2026

Related U.S. Application Data
(60) Provisional application No. 63/777,890, filed on Mar. 26, 2025.

(51) Int. Cl. G06F 30/18

(52) U.S. Cl. CPC G06F 30/18

(57) ABSTRACT

According to some embodiments systems and methods are provided including a memory storing processor-executable program code: and a processing unit to execute the processor-executable program code to cause the system to: receive a load interconnection request including a load profile; generate load forecast values; generate, using a machine learning (“ML”) model, a pruned list of load scenarios based on the generated load forecast values, wherein each load scenario included in the pruned list includes at least one grid violation; generate a resolution plan for overcoming each grid violation, the resolution plan based on simulated solutions; and generate a load interconnection summary report including the generated mitigation plan for the pruned list of load scenarios. Numerous other aspects are provided.

### CROSS-REFERENCE TO RELATED APPLICATION

The present application claims the benefit of U.S. Provisional Patent Application No. 63/777,890, entitled “SYSTEM AND METHOD FOR MACHINE LEARNING-ACCELERATED GRID LOAD INTERCONNECTION AND UPGRADE RECOMMENDATIONS” filed Mar. 26, 2025. The entire content of that application is incorporated herein by reference.

### BACKGROUND

An electric grid is a massive, interconnected network designed to generate, transmit, and distribute electricity generated by power plants to homes, business, industries, charging stations, etc. The electric grid connects the electricity source to electricity recipient through high-voltage transmission lines, substations and distribution lines to ensure a reliable, real-time balance of energy supply and demand. The grid requires instant, 24/7 balancing of supply and demand to maintain stability and avoid electric grid outages. The electric grid faces growing interconnection challenges due to surging electricity demand (e.g., projected to triple by 2050) and rapid deployment of distributed energy resources (DER), driven by electric vehicles, data centers, manufacturing growth, etc. Interconnection is the process of connecting customer systems to the electric grid. The first step in getting interconnected is to submit a load interconnection request. A load interconnection request is a formal application submitted to a transmission provider (e.g., utility company), by a customer who wants to connect a new or modified load (electricity consumption) to the electric grid, ensuring safe and reliable connection. Non-exhaustive examples of loads include a new data center, a large manufacturing facility, an electric vehicle (EV) charging station, which may cause a significant increase in electricity usage due to electrification or other reasons. After submitting the request, the utility provider assesses the impact of the new load on the grid and determines any necessary upgrades or modifications to the electric grid. The assessment may be via technical evaluations, including feasibility studies and system impact studies, to ensure the electric grid can handle the connection without causing instability in the electric grid. However, semi-manual engineering processes cause the review of the load interconnection requests to be extremely slow, each often taking one to two months, limiting the ability to efficiently evaluate and optimize the upgrades. Further, grid upgrades are conventionally slow and costly, hindering quick interconnection service.

It would be desirable to provide improved systems and methods to accelerate the evaluation process of the load interconnection requests and facilitate accurate decision making. Moreover, the results should be easy to access, understand, interpret, update, etc.

### SUMMARY

According to some embodiments, systems and methods are provided to automate end-to-end load interconnection assessment processes and provide recommendations for resolving anticipated violations within a short timeframe.

According to some embodiments, a computing system may include a memory storing processor-executable program code: and a processing unit to execute the processor-executable program code to cause the system to: receive a load interconnection request including a load profile and the date of interconnection; generate load forecast values; generate, using a machine learning (“ML”) model, a pruned list of critical load scenarios based on the generated load forecast values, wherein each load scenario included in the pruned list includes at least one grid violation; generate a resolution plan for overcoming each grid violation, the resolution plan based on simulated solutions; and generate a load interconnection summary report including the generated mitigation plan for the pruned list of critical load scenarios.

According to an aspect of another example embodiment, a method may include: receiving a load interconnection request including a load profile and the date of interconnection; generating load forecast values; generating, using a machine learning (“ML”) model, a pruned list of load scenarios based on the generated critical load forecast values, wherein each load scenario included in the pruned list includes at least one grid violation of a current violation or a voltage violation; generating a resolution plan for overcoming each grid violation, the resolution plan based on simulated solutions; and generating a load interconnection summary report including the generated mitigation plan for the pruned list of critical load scenarios.

A technical effect of some embodiments of the invention is an improved and computerized way to automate the load interconnection assessment process end-to-end, and provide recommendations for resolving anticipated grid violations within a short timeframe. Embodiments provide the use of machine learning (“ML”) models and Graphics Processing Unit (“GPU”) acceleration to analyze and validate load interconnection requests through continuous power flow and optimal power flow simulations. Embodiments provide accurate load interconnection assessments along with recommended grid upgrades or bridging solutions, which would otherwise be infeasible to compute using conventional semi-manual techniques in a limited time frame. Embodiments use adversarial training with various kinds of perturbations to create ML models (e.g., Graph Neural Network (GNN)-based classifier) that are robust in their predictions. Using the ML models, embodiments accurately reduce thousands of operating scenarios to a few critical representative scenarios for further analysis. The automated bridging solution workflow evaluates the critical representative scenarios with various grid operation (e.g., with existing DERs and switching) and infrastructure upgrade recommendations (e.g., with new DERs, regulation devices, and substation upgrades) using GPU acceleration. Embodiments facilitate quick and efficient decision making for load interconnection requests. As a non-exhaustive example, the end-to-end automated process provided by embodiments may be completed in less than one day. Embodiments, via automation, simulation, ML-drive prioritization, and bridging solutions, provide a scalable, efficient, and technically robust framework for providing load interconnection request assessments, which are critical for grid reliability and scalability in the clean energy transition.

### BRIEF DESCRIPTION OF THE DRAWINGS

FIG. 1 is a diagram illustrating a power system for delivering electricity to a customer in accordance with an example embodiment.

FIG. 2 is a diagram illustrating a network topology of an electric grid.

FIG. 3 is a block diagram of a system architecture according to some embodiments of the present invention.

FIG. 4 illustrates a system to generate training data according to some embodiments of the present invention.

FIG. 5 is a graph according to some embodiments of the present invention.

FIG. 6 is a process flow according to some embodiments of the present invention.

FIG. 7 is a Load Interconnection Data Detail User Interface (UI) according to some embodiments of the present invention.

FIG. 8 is a Summary Report UI according to some embodiments of the present invention.

FIG. 9 is a shortened list process flow according to some embodiments of the present invention.

FIG. 10 is a block diagram of the shortened list process flow according to some embodiments of the present invention.

FIG. 11 is a cluster graph according to some embodiments of the present invention.

FIG. 12 is a bridging solution process flow according to some embodiments of the present invention.

FIG. 13 is a block diagram of an apparatus according to some embodiments of the present invention.

FIG. 14 illustrates a tablet computer displaying a load interconnection analysis summary report user interface in accordance with some embodiments.

Throughout the drawings and the detailed description, unless otherwise described, the same drawing reference numerals will be understood to refer to the same elements, features and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the generic principles defined herein may be applied to other embodiments and applications without departing from the spirit and scope of the disclosure. Moreover, in the following description, numerous details are set forth for the purpose of explanation. However, one of ordinary skill in the art should understand that embodiments may be practiced without the use of these specific details. In other instances, well-known structures and processes are not shown or described in order not to obscure the description with unnecessary detail. Thus, the present disclosure is not intended to be limited to the embodiments shown but is to be accorded the widest scope consistent with the principles and features disclosed herein. It should be appreciated that in development of any such actual implementation, as in any engineering or design project, numerous implementation-specific decisions must be made to achieve the developer's specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

One or more embodiments or elements thereof can be implemented in the form of a computer program product including a non-transitory computer readable storage medium with computer usable program code for performing the method steps indicated herein. Furthermore, one or more embodiments or elements thereof can be implemented in the form of a system (or apparatus) including a memory, and at least one processor that is coupled to the memory and operative to perform exemplary method steps. Yet further, in another aspect, one or more embodiments or elements thereof can be implemented in the form of means for carrying out one or more of the method steps described herein; the means can include (i) hardware module(s), (ii) software module(s) stored in a computer readable storage medium (or multiple such media) and implemented on a hardware processor, or (iii) a combination of (i) and (ii); any of (i)-(iii) implement the specific techniques set forth herein.

The present invention provides significant technical improvements to facilitate the automatic evaluation of load interconnection requests. Automating evaluation of load interconnection requests, as described by embodiments, results in more efficient and accurate assessment of load interconnection requests in a way to better provide access to the electric grid while avoiding instability in the electrical grid. The present invention is directed to more than merely a computer implementation of a routine or conventional activity previously known in the industry as it significantly advances the technical efficiency by implementing a specific new method and system as defined herein. The present invention is a specific advancement in the area of electrical grid operations by providing benefits in improved accuracy and reduced time to connect to the electrical grid, and such advances are not merely a longstanding commercial practice. The present invention provides improvement beyond a mere generic computer implementation as it involves the processing and conversion of significant amounts of data in a new beneficial manner.

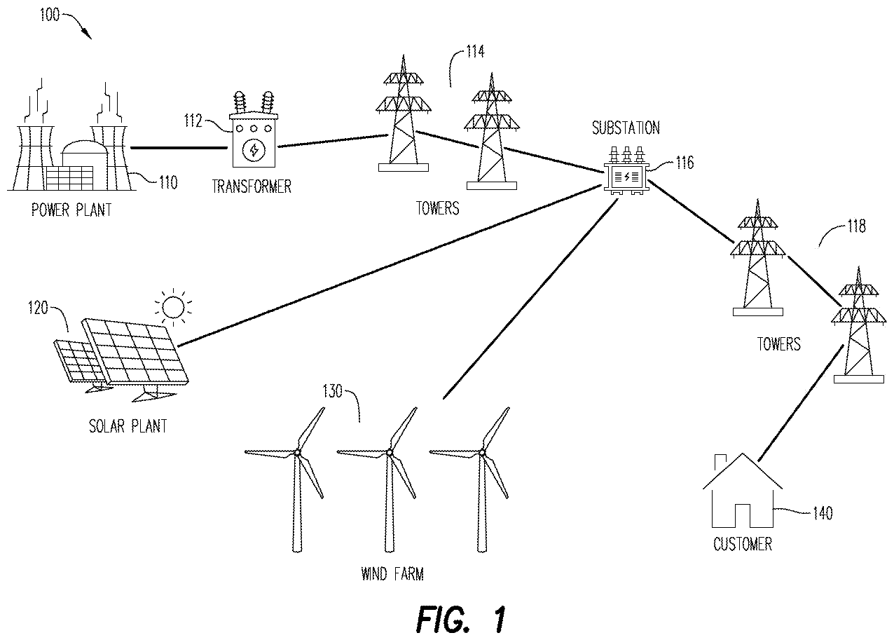

FIG. 1 illustrates a power delivery system 100 showing components that can facilitate the generation of power and the process of delivering power (e.g., delivering energy, electricity) to customer premises 140. Electric power can be generated at a power generation facility (power plant 110), passed to a transformer 112 and then carried by transmission lines/towers 114 via power lines to substations 116 having transformers. A local distribution system of smaller, lower-voltage transmission lines/towers 118 and substations carry power to the customer premises 140. In the example of FIG. 1, the power delivery system 100 may also include renewable sources of power including a solar plant 120 and a wind farm 130. As in the case of the power plant 110, the solar plant 120 and the wind farm 130 can generate electric power which is passed to a point on the grid (e.g., substation 116, etc.) and carried to the customer premise 140 just as the power from the power plant 110.

A variety of facilities can generate electric power including both power plants and renewable energy sources. For example, power generation facilities (e.g., power plant 110, etc.) can include power plants that burn coal, oil, or natural gas. As another example, power generation facilities can include nuclear power plants, renewable sources of energy (e.g., solar plant 120, wind farm 130, etc.) such as hydroelectric dams, wind turbines, and solar panels, and the like. The location of these power generation facilities, and their distance from end users, can vary widely.

The electricity that is generated by the power generation facilities may be stepped up or stepped down by transformers (e.g., transformer 112) which may be located at power plant substations adjacent to (and connected via power lines to) the power plant. For example, a transformer may be a step-up transformer that will “step up” the voltage of the electricity. When power travels through power lines (e.g., metallic wires that conduct electricity), some of that power is wasted in the form of heat. The power loss is proportional to the amount of current being carried. Power companies keep the current low and compensate by stepping up the voltage. After the voltage is stepped up, the electricity is typically carried over long distances by high voltage power transmission lines, typically supported and elevated by transmission towers (e.g., transmission lines/towers 114 and 118) that can be of various dimensions, materials, and heights. Of note, power lines can also be buried under the ground. Of note, substations can contain a variety of other equipment, including switches, breakers, regulators, batteries, etc.

Customer premises (e.g., customer premise 140, etc.) can be of any type and variety. Customer premises can be a residential customer premises, such as residential houses. Customer premises can be an industrial customer premises, such as factories. Customer premises can be commercial customer premises, such as an office building. If a particular customer premises has a heavier load (e.g., has a higher demand for power), then a larger transformer, instead of a pole transformer, might service that particular customer premises.

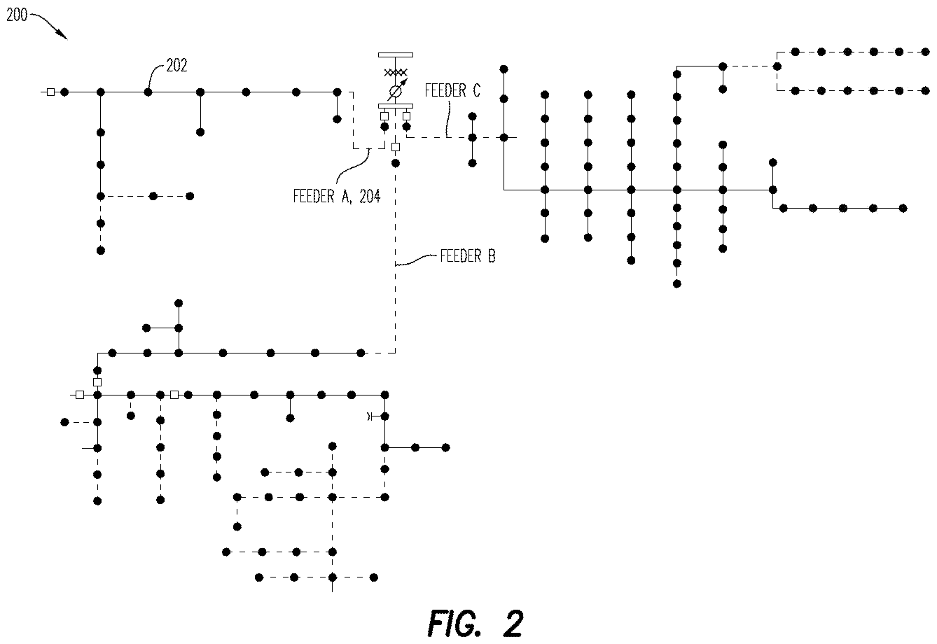

FIG. 2 depicts a topological illustration of a power grid system 200 (e.g., an electrical grid) comprising multitudes of nodes 202. In this example, a node may represent a bus (e.g., where multiple components including but not limited it to, generators, transmission lines, transformers and loads, are connected together to facilitate the transfer of power), and each edge represents a connection between busses. The power grid system 200 may follow a structural topology, influenced by factors such as budget, system reliability, load demand (demand for power), land, and geology. The topology refers to how the nodes 202 are connected to the feeder 204. The feeder 204 is a high-capacity conductor or line that transports electricity from a substation or power source to distribution points, such as transformers or large, industrial end-users. Unlike distribution lines, feeders typically do not have direct user taps along their length. Feeders are essential for carrying power to specific areas and unlike branches, maintain a consistent current flow from end to end. Based on some switches in the network, connections (and topology) may change. The structural topology in many cities and towns, for example many of those in North America, tends to follow a classic radial topology. This is a tree-shaped network wherein power from larger voltage lines and substations radiates out into progressively lower voltage lines and substations until the customer premises is reached. Other topologies can be mesh topologies, loped systems (mostly found in Europe) and ring networks.

As described above, the rapid growth of the electrical grid from the electrification of transportation and industry, new data centers and high Distributed Energy Resource (DER) penetration is resulting in huge volumes of load interconnection requests for the utility sector. For example there is a prediction of three times the electricity demand by 2050, and 217 GW of added DER capacity through 2028 in the United States. A load interconnection request is a formal application submitted to a transmission provider (e.g., utility company), by a customer who wants to connect a new or modified load (electricity consumption) to the electrical grid, ensuring safe and reliable connection. Non-exhaustive examples of loads include a new data center, a large manufacturing facility, an electric vehicle (EV) charging station, or other suitable elements which results in a significant increase in electricity usage. The request typically includes information about the property, electricity usage history, and the specifics of the new or modified load (equipment, system size, location, etc.) After submitting the request, the utility provider assesses the impact of the new load on the electrical grid and determines any necessary upgrades or modifications. However, semi-manual engineering processes cause the review of the load interconnection assessments to be extremely slow (e.g., 1-2 months), limiting the ability to efficiently evaluate and optimize upgrades. As part of the conventional load interconnection request analysis, a load interconnection feasibility study is performed to assess if the electrical grid can support a new, large power load without compromising reliability. Among other steps, the load interconnection feasibility study includes a power flow analysis. The power flow analysis involves a significant number of simulations as it simulates the grid under normal and contingency conditions to determine if the new load causes voltage violations or overloads in transmission lines or transformers. While a single power flow calculation determines the steady-state operation condition of a grid at a specific moment, practical applications require running thousands of scenarios to ensure reliability. Often time-series simulations are performed, analyzing grid behavior over hours, days, or years (e.g., QSTS—Quasi-Steady State Time Series) to account for fluctuating solar/wind generation and load changes. Further, grid upgrades are conventionally slow and costly, hindering quick interconnection service.

To address these problems, the automated load interconnection tool provided by embodiments automatically and dynamically generates an automated workflow to analyze and validate an interconnection assessment process through machine learning, continuous power flow and optimal power flow simulations. The automated load interconnection tool provides an end-to-end load interconnection assessment in three phases—a shortlist phase, a resolution phase and a summarize phase. In the shortlist phase, user input is processed, forecast data is generated, critical days are identified, and scheduled JavaScript Object Notation (JSON) payloads of short listed scenarios are created/uploaded for analysis. In the resolution phase, bridging solutions (violation resolution) are performed, and network violations are compared against thresholds to determined acceptance or rejection of the request. In the summarize phase, the results of the short list phase and resolution phase are reported.

It is noted that traditional planning tools often differ from the operation tools, which may result in inconsistent load interconnection decision making. To address this, embodiments leverage Artificial Intelligence and machine learning to predict potential grid violations and pinpoint diverse critical representative days (e.g., with a significant number of violations) which are then solved by operation tools that using detailed physics based “optimal power flow” solvers.

Embodiments provide an accurate load interconnection assessment, along with recommended grid upgrade/bridging solutions, which would otherwise be infeasible to compute using existing semi-manual techniques in a limited timeframe. The automated load interconnection tool accurately reduces thousands of simulated operating scenarios to a few critical and diverse representative scenarios using ML-based methods based on likelihood violations. Embodiments use adversarial training with various kinds of perturbations to create ML models that are robust in their predictions. One or more embodiments use humble AI methods to detect drift, and large extrapolation is used to infer if the model can be trusted at inference time.

The automated load interconnection tool of embodiments further provides precise recommendations for resolving anticipated violations stemming from the request. The recommendations may be referred to herein as “bridging solutions”, and may be provided within a short time frame by using continuous simulation using a Distributed Energy Resource Management System (DERMS). The bridging solutions may consider operational changes for existing Distributed Energy Resources (DERs), infrastructure changes with multiple relocatable energy storage systems (RESS), and load curtailment via a load control management system (“LCMS”).

Pursuant to embodiments and as a non-exhaustive example, the end-to-end analysis for a single critical day may be run within two hours by considering existing DERs, 1-3 additional RESS, and LCMS. This indicates that even if about twelve diverse critical days are screened out, the analysis can be potentially completed within a day, thereby significantly accelerating and reforming the conventional semi-manual assessment processes.

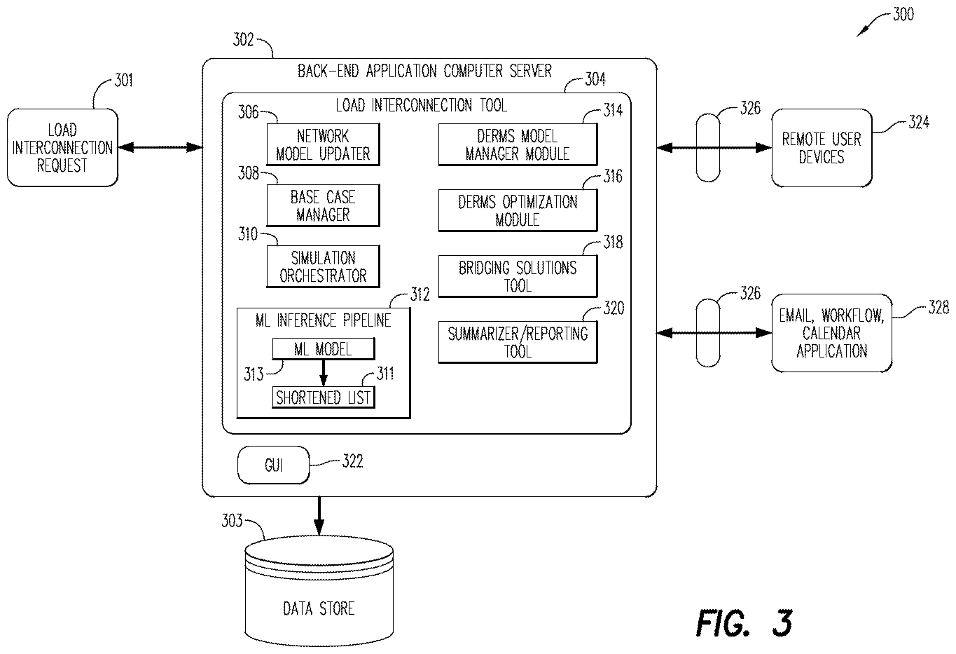

FIG. 3 is a high-level block diagram of a load interconnection framework or system 300 according to some embodiments of the present invention. In particular, the system 300 includes a back-end application computer server 302 that may access information in data store 303 (e.g., storing a set of electronic records). The back-end application computer server 302 may also access information from other data stores or sources. The information may be accessed in connection with a load interconnection tool 304 that applies machine learning or artificial intelligence algorithms and/or models to received data and the electronic records. The back-end application computer server 302 and/or any of the other devices and methods described herein, may be hosted in a cloud-based environment (e.g., on a cloud platform) or an on-prem environment.

The load interconnection tool 304 may include a network model updater 306, a base case manager 308, a simulation orchestrator 310, a Machine Learning (“ML”) inference pipeline 312, a DERMS model manager module 314, a DERMS Optimization module 316, a bridging solutions tool 318, and a summarizer/reporting tool 320.

The network model updater 306 receives a network model (e.g., a Common Information Model (CIM) model) from a utility source. As described further below, the utility source submits the load interconnection request for the new load interconnection. The network model updater 306 may add the new load interconnection to the network model as a battery energy storage system with the user-specified kVA size. The load interconnection battery is added to the network model at the correct transformer using the appropriate structure and circuit IDs. During execution of the bridging solutions tool 318, the network model updater 306 may add during simulations “mobile” battery energy storage systems at a location of the load interconnection automatically based on user configuration as a bridging solution. The system may be configured to add any number of “mobile” battery energy storage systems.

The base case manager 308 reads the utility-specific format of load and generation (load/gen) data. The load/gen data may be provided from at least one of an external data source (e.g., utility) or simulation, for a pre-determined network topology. Load and generation data represents electricity demand from consumers, while generation data represents electricity supply from producers (power plants, renewables, etc.). In particular, load data (demand) measures the consumption of electricity, including peak load (highest demand times) and base load (minimum continuous demand); and generation data (supply) tracks the amount of electricity produced by power sources, including scheduled, semi-scheduled, and non-scheduled units, often including renewable output (wind/solar) and total capacity. The base case manager 308 extracts, transforms and stores load/gen forecasts (generated by the simulation orchestrator 310). The base case manager 308 may create JSON payloads including load/gen/capacitive/tap (connection point on transformer)/control-mode for a select date for the resolution phase. In one or more embodiments, the base case manager 308 maintains aggregate transformer level load/gen values to be used to generate forecasted values. Pursuant to embodiments, the base case manager 308 may be configured to run once to initialize the system or it may be re-run as needed (e.g., in a case the forecast data or the network model changes).

The simulation orchestrator 310 receives the user input of the load interconnection request, invokes parts of the network model updater 306 and base case manager 308 to generate, using growth profiles and energization date, forecast data for the new load interconnection. The energization date is the planned/scheduled date for the initial power-on of the new load being connected to the electrical grid and energized. Load/gen forecast data predicts future electricity demand (load) and available energy production (generation) over various time frames. Inputs used to generate the load/gen forecast include, but are not limited to, weather (e.g., temperature, humidity, wind speed, and cloud cover are critical for predicting heating/cooling demand), historical data (e.g., previous consumption patterns per load/gen datasets), economic and social factors (e.g., population growth, Gross Domestic Product, industrial activity), and new technologies (e.g., adoption of electric vehicles (EVs), building electrification, and behind-the-meter solar).

The simulation orchestrator 310 also invokes the ML inference pipeline 312 to: generate critical dates, prepare schedule data for analyzing the critical dates, analyze and validate the critical dates with physics based power flow, compare violations with user specified thresholds, indicate accept/reject for the load interconnection request, and provides links to the detailed results.

The simulation orchestrator 310 may also be configured to create problem formulations and trigger the DERMS optimization module 316 once to initialize the system and/or other user-defined times. The simulation orchestrator 310 may be further configured to run any stage of the bridging solution output by the bridging solutions tool 318. The user may further configure the simulation orchestrator 310 to consider voltage and thermal violation thresholds as counts of violations acceptable in a given solution. In this case, the simulation orchestrator 310 runs all the stages configured by the user and automatically compares the resulting violations with the acceptable violation threshold and indicates on the user interface if the proposed bridging solution can be accepted or rejected. In a case the proposed solution is rejected based upon the violation threshold, the simulation orchestrator 310 may automatically move on to a the subsequent stage. In a case the proposed solution is accepted, the simulation orchestrator 310 may will abort the execution of the further stages. The simulation orchestrator 310 also updates the user interface with direct links to a DERMS optimization solution dashboard for every solution.

The ML inference pipeline 312 includes a trained violation prediction ML model 313 that detects “violations” in time-series transformer data, clusters critical events, and exposes both a REST API and an interactive dashboard. As used herein, a “violation” may refer to an overcurrent (i.e., excess current flows through a conductor, exceeding its designed capacity), an overvoltage (i.e., voltage in a circuit exceeds its normal operative level or maximum design limit), an under voltage (i.e., voltage supply drops below the nominal, safe operating level for an extended period), thermal overloading (i.e., power flow exceeds safe operating limits), transient or fault conditions (i.e., short-circuit faults), or other power flow violations.

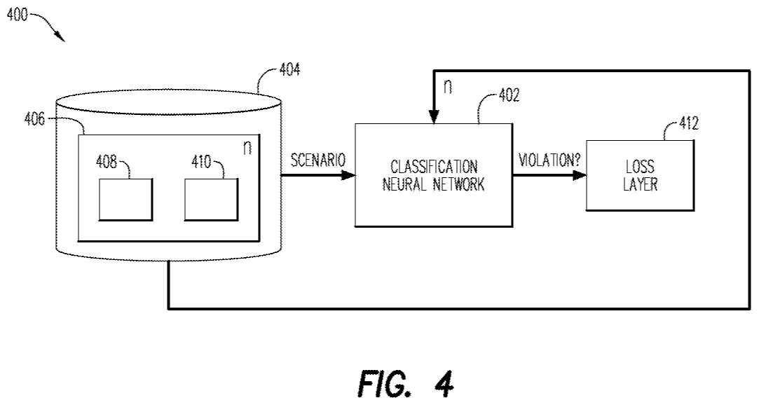

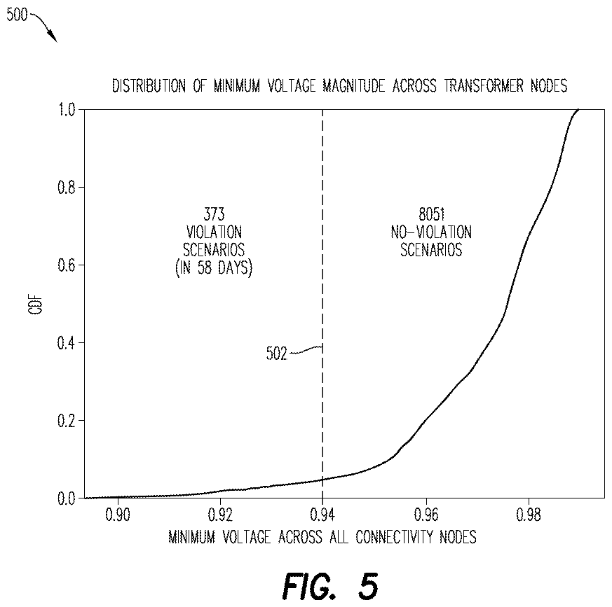

Pursuant to embodiments, the violation prediction ML model 313 is trained, as described further below with respect to FIGS. 4 and 5. The ML model 313 may be one of a neural network or a graph neural network, or other suitable ML model. The trained violation prediction ML model 313 receives the load/gen forecast data containing the load interconnection generated by the simulation orchestrator 310, and generates a list of predicted hourly violation scenarios. The input forecast data may include hourly scenarios with P and Q loads (x variables). As used herein, a scenario is a point in time including the forecasted loads and the corresponding voltage magnitude values for that point in time. While the scenarios described herein designate an hour as the point in time, other suitable time measures may be used. As also used herein, P load refers to an active power load and Q load refers to a reactive power load. In power system simulations, a P/Q load represents a device where the active power (P) and reactive power (Q) are specified. To distinguish between voltage violations and non-violations, voltage magnitudes are converted into binary voltage violation labels based on pre-specified threshold. For each hourly scenario, a binary graph-level voltage violation label (Y variable) is defined, where a value of 1 indicates a violation at any voltage measurement point, while a value of 0 indicates no violations. The violation prediction ML model 313 is then used on the X and Y variables to predict graph-(or node-) level violations. For days identified in the list of predicted hourly violation scenarios, daily scenario characteristics, including, but not limited to, time of day, are extracted. The violation prediction ML model 313 then applies clustering techniques to group similar violation days, and then selects a critical/representative daily scenario from each cluster. The selected critical/representative scenarios together form the pruned (shortened) list of load scenarios. It is noted that the violation prediction ML model 313 is configurable to output any number of critical/representative days, as decided by a user. It is noted that while the Y variables are described with respect to a binary classification, in other embodiments, regression classification may be used, providing for assessment of violation severity and distribution.

The DERMS model manager module 314 is a data ingestion and asset modeling service. The DERMS model manager module 314 may be used by utilities and other electrical grid operators to manage the increasing amount of renewable energy on the grid by controlling and optimizing the flow of electricity from distributed energy resources (DER) such as solar panels and wind turbines.

The DERMS Optimization module 316, a component of the DERMS model manager module 314, provides for the automated optimal scheduling of DERs and other controllable assets across real-time and look-ahead time horizons. The DERMS Optimization module 316 supports utilities in maintaining reliability by proactively managing constraints stemming from existing and anticipated DER connections. Optimization provides situational awareness of both real-time (intraday) and look-ahead (day(s) ahead) grid constraints. Leveraging these insights, the DERMS Optimization module 316 recommends DER dispatch instructions that minimize those constraints and optimally align with technical and economic objectives. Additionally, the DERMS Optimization module 316 may identify grid violations in advance (e.g., thermal and/or voltage violations in the next 24 hours), and reduce the violations by optimally dispatching or constraining DERs in advance (e.g., curtailing photovoltaic (PV) systems, optimally charging and discharging batteries).

The DERMS Optimization module 316 performs power flow, optimal power flow or non-power flow based “heuristic” optimization analyses using as-operated network models, real-time measurements, load and generation forecasts, and planned switch changes. Pursuant to some embodiments, the DERMS Optimization module 316, using a physics-based power flow, may verify the selected critical/representative days are days with high numbers of voltage violations. The DERMS Optimization module 316 may also be used by the bridging solutions tool in the evaluation of different bridging solutions.

The back-end application computer server 302 may also utilize a Graphical User Interface (“GUI”) 322 to view, analyze, and/or update the electronic records. The back-end application computer server 302 may also exchange information with a remote user device 324 (e.g., via communication port 326 that might include a firewall). Back-end application computer server 302 may also transmit information directly to an email server (or postal mail server), a workflow application, and/or a calendar application 328 to facilitate recommendation processing and alerts. For example, the remote user device 324 may transmit an interconnection request to the back-end application computer server 302. Based on the request, the back-end application computer server 302 may retrieve information and/or adjust data in the data store 303.

Presentation of a user interface via the GUI 322 may include any degree or type of rendering, depending on the type of user interface code generated by the back-end application computer server 302. For example, a user (not shown) may execute a Web Browser to request and receive a Web page (e.g., in HTML format) from back-end application computer server 302 via HTTP, HTTPS, and/or WebSocket, and may render and present the Web page according to known protocols.

The back-end application computer server 302 and/or the other elements of the system 300 might be, for example, associated with a Personal Computer (“PC”), laptop computer, smartphone, an enterprise server, a server farm, and/or a database or similar storage devices.

According to some embodiments, an “automated” back-end application computer server 302 (and/or other elements of the system 300) may facilitate access, analysis, and/or update of electronic records in the data store 303. As used herein, the term “automated” may refer to, for example, actions that can be performed with little (or no) intervention by a human.

As used here, devices, including those associated with the back-end application computer server 302 and any other device described herein, may exchange information via any communication network which may be one or more of a Local Area Network (“LAN”), a Metropolitan Area Network (“MAN”), a Wide Area Network (“WAN”), a proprietary network, a Public Switched Telephone Network (“PSTN”), a Wireless Application Protocol (“WAP”) network, a Bluetooth network, a wireless LAN network, and/or an Internet Protocol (“IP”) network such as the Internet, an intranet, or an extranet. Note that any devices described herein may communicate via one or more such communication networks.

The back-end application computer server 302 may store information into and/or retrieve information from data store 303. The data store 303 may be locally stored or reside remote from the back-end application computer server 302. As will be described further below, the data store 303 may be used by the back-end application computer server 302 in connection with an interactive user interface to access, analyze and update electronic records. Although a single back-end application computer server 302 is shown in FIG. 3, any number of such devices may be included. Moreover, various devices described herein might be combined according to embodiments of the present invention.

The back-end application computer server 302 may be separated from or closely integrated with the data store 303. A closely-integrated server 302 may enable execution of services completely on the database platform, without the need for an additional server. For example, back-end application computer server 302 may provide a comprehensive set of embedded services which provide end-to-end support for Web-based applications. The services may include a lightweight web server, configurable support for Open Data Protocol, server-side JavaScript execution and access to SQL and SQLScript. The back-end application computer server 302 may provide application services (e.g., via functional libraries) using services that manage and query the database files stored in the data store 303. The application services can be used to expose the database data model, with its tables, views and database procedures, to clients. In addition to exposing the data model, the back-end application computer server 302 may host system services such as a search service, and the like.

Note that the system 300 of FIG. 3 is provided only as an example, and embodiments may be associated with additional elements or components. According to some embodiments, the elements of the system 300 automatically transmit information associated with an interactive user interface display over a distributed communication network.

FIG. 4 illustrates a system 400 for training the classification neural network 402 to output a trained violation prediction ML model 313 according to some embodiments.

Each neural network may comprise a network of neurons which receive input, change internal state according to that input, and produce output depending on the input and the internal state. The output of certain neurons is connected to the input of other neurons to form a directed and weighted graph. The weights as well as the functions that compute the internal state can be modified by a training process based on ground truth data as is known in the art. The neural networks may comprise any one or more types of suitable artificial neural network that are or become known, including but not limited to convolutional neural networks, recurrent neural networks, long short-term memory networks, deep reservoir computing and deep echo state networks, deep belief networks, and deep stacking networks.

Training data 404 comprises n sets 406, where each set includes hourly load forecast scenarios 408 and a corresponding violation scenario indicator 410 (e.g., violation or non-violation). For each scenario, P and Q loads are specified at the transformer level, and voltage magnitude is measured at the transformer nodes. The violation scenario indicator 410 associated with each scenario may have been generated by a violation scenario indicator process. As a non-exhaustive example of the violation scenario indicator process, a DERMS optimization module 316 can be used to generate the training labels (violation and non-violation) and then identify the input scenarios as violation or non-violation and store the identifications in a repository. For each scenario, reviewers may classify each scenario as having a violation indicator or a non-violation indicator.

One or more embodiments may determine training data for the neural network (i.e., the ground truth resolution corresponding to a given scenario). In the parlance of neural network training, each violation scenario indicator 410 is considered ground truth data corresponding to the respective hourly load forecast scenario 408. In one or more embodiments, the sets 406 may be stored in a database, or any other suitable store.

Based on its initial configuration and design, the neural network 402 outputs a predicted violation status for a scenario. Loss layer component 412 determines a loss by comparing the predicted violation indicator for a given load forecast scenario 408 with the actual violation indicator 410 associated with the scenario within the sets of scenario-violations indicators 406. A loss is determined for each input load forecast scenario 408 in order to determine a total loss. The loss may comprise an L1 loss, an L2 loss, or any other suitable measure of total loss known in the art.

The total loss is backpropagated from loss layer component 412 to the neural network 402. As is known in the art, the internal weights of the neural network 402 are modified in response to the total loss. The foregoing process repeats until it is determined that the total loss has reached an acceptable level or training otherwise terminates.

At termination of the training, the trained neural network may be a trained system model including information about a decision boundary created via the supervised learning. The decision boundary may be a boundary that separates the scenarios into particular categories (e.g., violation or non-violation). Thus, a decision boundary may be automatically calculated for a model using supervised learning. According to some embodiments, the decision boundary might be associated with a line, a hyperplane, a non-linear boundary separating one category from another category, and/or a plurality of decision boundaries. Moreover, a decision boundary might comprise a multi-class decision boundary separating multiple categories.

As a non-exhaustive example, FIG. 5 includes a graph 500 of a cumulative distribution function of the minimum voltage magnitude across transformer nodes. Here, with a threshold 502 of 0.94 p.u, there are 373 scenarios with violation indicators (violation scenarios) and 8,051 scenarios with non-violation indicators (non-violation scenarios) in a dataset including 8,424 hourly scenarios. It is noted that to address the high dimensionality of the P and Q loads, principal component analysis (PCA) was performed. PCA indicated P and Q loads are highly correlated, and for ML model development, the first ten principal components were selected as features. The dataset was divided into training, validation, and test sets, with stratified sampling being employed to ensure that both violation and non-violation classes were proportionally represented in all three sets. Class weights were assigned to the classification neural network to address class imbalance.

The system 400 may comprise any system or systems for training an artificial neural network that are or become known. For example, training system 400 may employ any of supervised learning, unsupervised learning and/or reinforcement learning as is known in the context of deep neural networks. Generative adversarial networks may be used including a generative and a discriminative network as is known.

Pursuant to some embodiments, Graph Neural Networks (GNN) may be used to output the trained violation prediction ML model 313. The GNN is a type of deep learning architecture that processes data represented as graphs (e.g., topology as shown in FIG. 2) including networks of nodes (entities) and edges (relationships). Here, the GNN leverages the topology to predict graph-level violations. Pursuant to some embodiments, the GNN may be trained to enable prediction of violations across diverse growth scenarios.

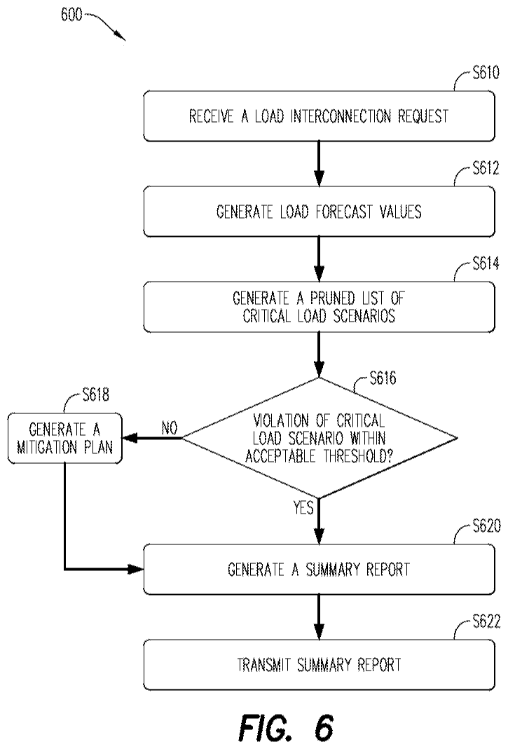

FIG. 6 illustrates a process 600 for generating a load interconnection request response according to some embodiments. The process 600 may be performed by some or all of the elements of the system 300 described with respect to FIG. 3, or any other system, according to some embodiments of the present invention. The flow charts described herein do not imply a fixed order to the steps, and embodiments of the present invention may be practiced in any order that is practicable. Note that any of the methods described herein may be performed by hardware, software, or any combination of these approaches. Program code embodying these processes may be stored by any non-transitory tangible medium, including a fixed disk, a volatile or non-volatile random-access memory, a DVD, a Flash drive, or a magnetic tape, and executed by any one or more processing units, including but not limited to a processor, a processor core, and a processor thread. For example, a computer-readable storage medium may store thereon instructions that when executed by a machine result in performance according to any of the embodiments described herein. Embodiments are not limited to the examples described below.

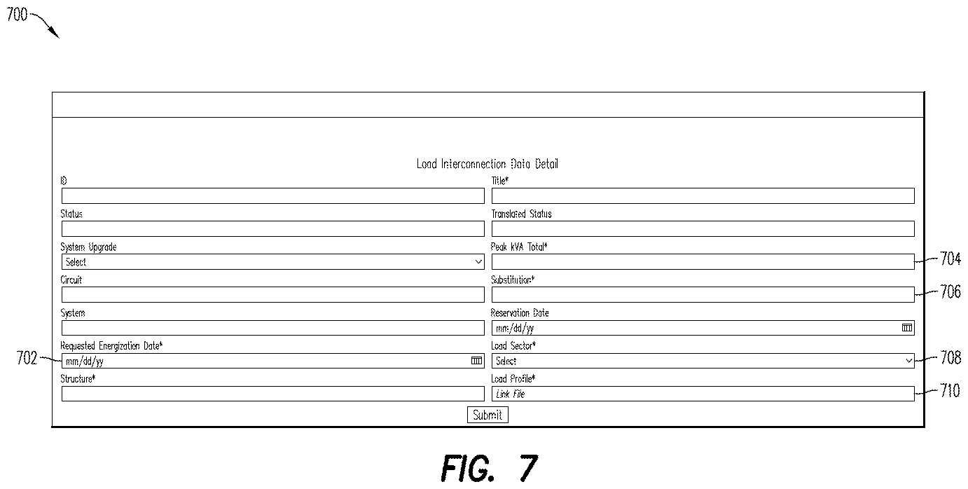

Initially, at S610, a load interconnection request 301 is received. The load interconnection request 301 may be received via a load interconnection data detail user interface 700 (FIG. 7). The load interconnection request may include one or more parameters including, but not limited to, a maximum load, a location, a date of energization request, a customer type, and a representative load profile based on load sector (e.g., commercial, industrial, residential, agricultural). The representative load profile is a graph or data set illustrating the typical electricity consumption pattern of a specific consumer type (e.g., residential, consumer, etc.) over a set period. The representative load profile may display at least one of hourly, daily, seasonal usage variations. The load interconnection data detail UI may require at least the requested energization date 702, peak/maximum kVA total 704, substation 706, load sector 708 and load profile 710.

Then, in S612, load forecast values are generated. The load forecast values may be based on the peak k Va multiplied by a growth profile (including the new interconnect) using the specified load sector and energization date in the load interconnection request. As described above, the simulation orchestrator 310 may initiate generation of the load forecast values for a defined time period (e.g., hourly) and/or time range (e.g., over three years). Each forecast value together with the time-period, for a pre-defined network topology, is an individual load scenario (“scenario”).

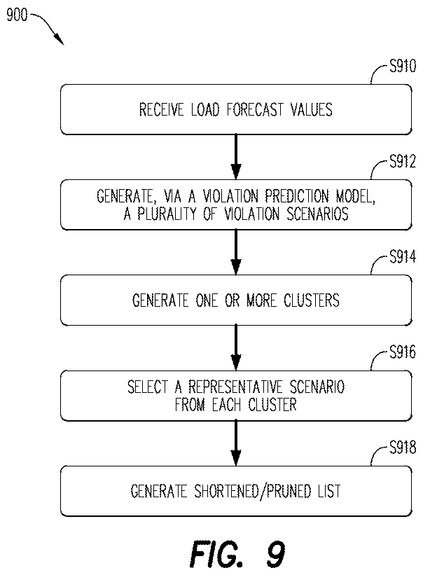

Next, at S614, a shortened (“pruned”) list of critical load scenarios 311 is generated via the trained violation prediction ML model 313, as described further below with respect to FIG. 9. Each critical load scenario included in the pruned list 311 includes at least one grid violation. The grid violation is at least one of a current violation and a voltage violation.

At S616 it is determined, using the physics-based power flow solver of the DERMS optimization module 316, for each critical load scenario in the pruned list of critical scenarios whether the identified critical load scenario includes violations that are within an acceptable threshold, validating the critical load scenarios in the pruned list. It is noted that pursuant to some embodiments, the critical load scenarios in the pruned list of critical scenarios are not validated (e.g., S616 is not part of the process and the critical load scenarios are not compared to a threshold) resulting in all of the critical scenarios proceeding directly to S618.

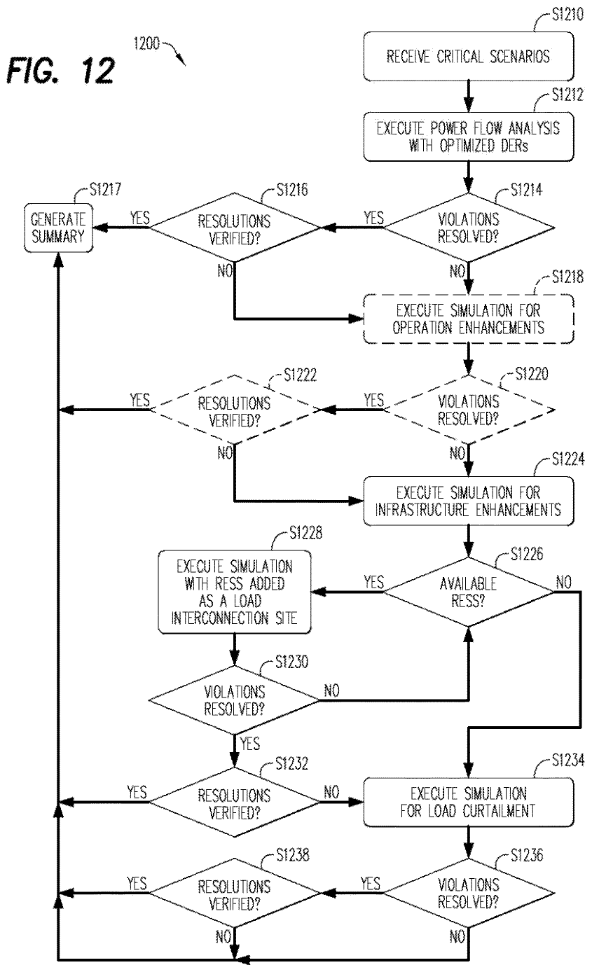

In a case it is determined at S616 the violations in the given critical load scenario are not within an acceptable threshold, the process proceeds to S618. In S618 the scenario is transmitted to the bridging solutions tool 318 and a resolution plan is generated for overcoming each grid violation in the scenario. As described further below with respect to FIG. 12, the bridging solutions tool 318 receives the pruned list of load scenarios; generates a bridging solution to resolve the violations included in the pruned list of load scenarios; executes a bridging solution simulation of the bridging solution; and determines whether the simulation resolves the violations or does not resolve the violations.

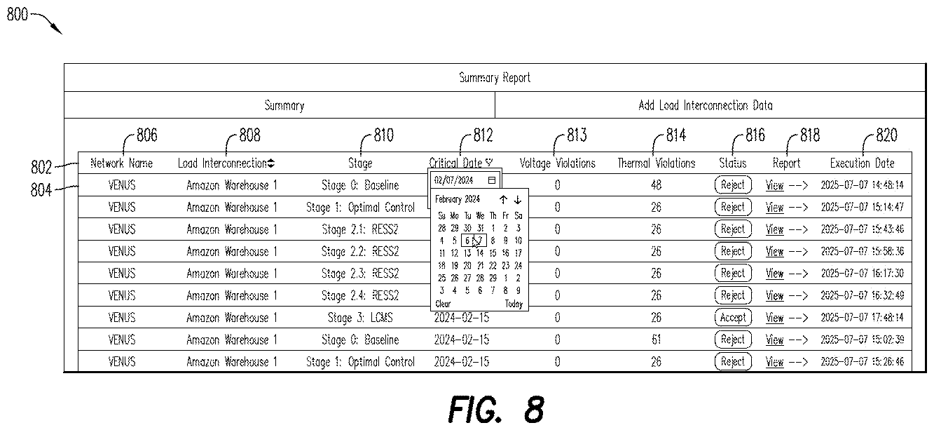

In S620, a summary report 800 (FIG. 8) including the resolution plan is generated. The summary report 800 is transmitted in S622 to at least one of: a remote user device 324, a user via an email, workflow, calendar application 328, and the DERMS model manager module 314. Pursuant to some embodiments, the DERMS model manager module 314 may initiate one or more tasks (e.g., initiate requisition of a battery) in response to receipt of the summary report.

FIG. 8 includes a summary report user interface (UI) 800 in accordance with some embodiments. The summary report UI 800 includes a list 802 of every solution that was executed. Each item 804 on the list 802 includes the name of the load interconnection 806, the name of the substation/network 808, the stage of the workflow 810, the critical date 812, the resulting voltage violation count 813 and the resulting thermal violation counts 814, the status of accept/reject based on the configurable acceptable violation threshold 816, a link 818 to the DERMS Optimization Solution Dashboard for more details, and the execution date/time 820. The stage of the workflow 810 refers to the different possible resolutions as described further below with respect to FIG. 12.

In a case it is determined at S616 the violations in the given critical load scenario are within an acceptable threshold, the process proceeds directly to S620 and the summary report is generated.

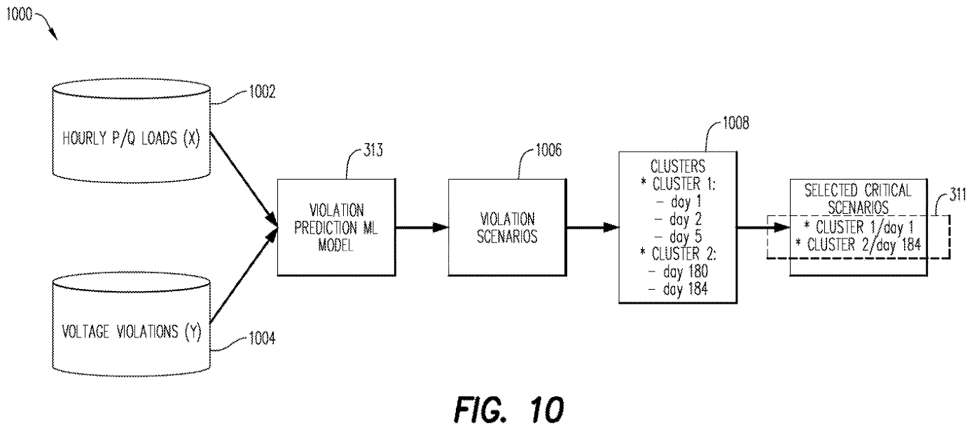

Turning to FIGS. 9 and 10, a process 900 (FIG. 9) and respective block diagram 1000 (FIG. 10) for generating a pruned/shortened list 311 is provided according to some embodiments.

Initially, at S910, the load forecast values (scenarios) are received as input to the trained violation prediction ML model 313. In particular, the input includes scenarios with P and Q loads and volage magnitudes for each measurement point (e.g., hourly), as the x-variables 1002, and binary graph-level voltage violation labels of one or zero as the y-variable 1004 (e.g., a value of one indicates a violation at any voltage measurement point, and a value of zero indicates no violations). Then at S912, execution of the trained violation prediction ML model outputs a plurality of violation scenarios 1006 with dates and hours that are predicted to have a grid violation.

Next, at S914, daily scenario characteristics (e.g., time of day) are extracted from the list of predicted violation scenarios 1006 and one or more clusters of days having similar patterns of violation values 1008 are created. For example, cluster 1 includes days 1, 2, and 5, and cluster 2 includes days 180 and 184. Any suitable clustering techniques may be used. It is noted that each cluster, irrespective of size, is relevant for downstream analysis. In some embodiments, the number of clusters may be defined based on machine learning to best represent the data, and a user may provide a maximum number of clusters to consider. In other embodiments, the user may ask for a specific number of clusters.

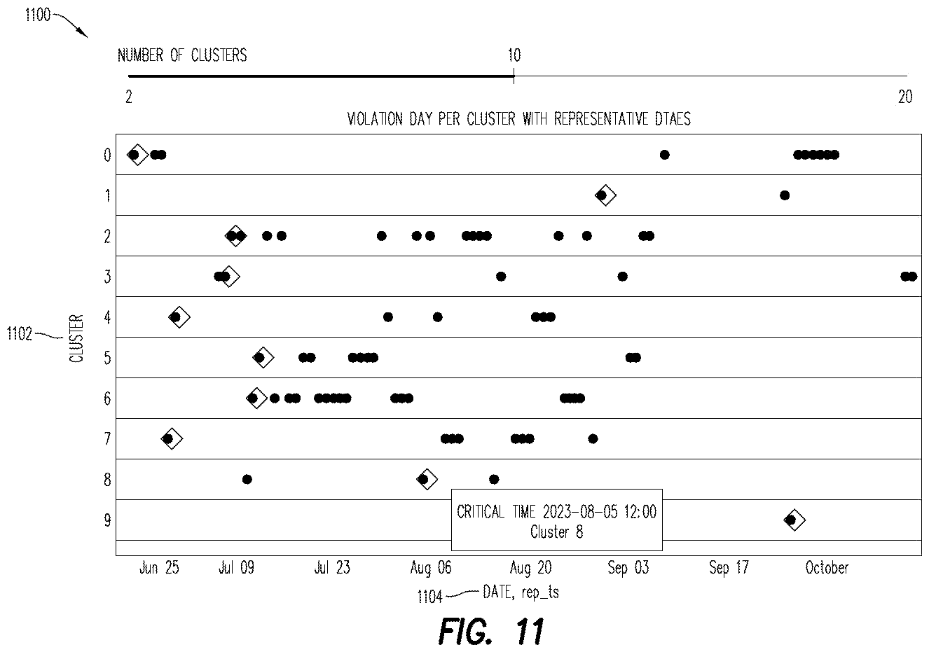

FIG. 11 includes a cluster user interface 1100. The cluster user interface 1100 includes the clusters (1102) present on a given day (1104) and may display the different clusters present for the given day. Here, June 25^{th} includes three clusters—Cluster 0, Cluster 4 and Cluster 7. Here, the maximum number of clusters to create is ten.

A representative daily scenario is selected, via the violation prediction ML model 313, from each cluster in S916. The representative daily scenario may be referred to as a “critical” scenario. Any suitable rules and criteria that may be applied from those scenarios may be used to select the critical scenario (e.g., the cluster has similar violations, and a rule selects the day with the maximum number of violations, etc.). The shortened/pruned list 311 is generated in S918 including the “critical” scenarios for further analysis, as described above with respect to FIG. 6.

Pursuant to some embodiments, the “critical” scenarios on the shortened list of violation scenarios are received by a physics-based power flow solver of the DERMS optimization module 316 for verification of the grid violations to reduce any false positives. The power flow solvers computes violations for the critical scenarios using physics-based models to verify that the violations are actually present in the critical scenario. The physics based power flow solver computes real violations (as opposed to the predictions of the ML model) using more parameters than the ML model (e.g., the same inputs as the ML model plus other inputs including, but not limited to, line impedances, and other network data submitted by the utility). Then the physics-based power flow solver compares the violations from the physics-based models with a user-defined threshold (e.g., if the violations are above the threshold, then the scenario is considered a critical scenario). It is noted that the physics-based power flow solver computes these violations independently for the shortlisted critical scenarios. It is further noted that executing the physics-based power flow is computationally expensive and not feasible for analyzing all the days of the year. Conventionally, deciding the days for which to perform physics-based power flow was a manual job based on operator judgment or some basic heuristics. Manually selecting these days has become less accurate and less reliable with increased variability in the grid due to increasing penetration of renewable resources, more DERs and more EV charging. However, it is feasible to execute physics-based power flow for the short-listed critical scenarios pursuant to some embodiments. In other embodiments, a physics-based power flow may not executed and the identified critical scenarios are not further verified.

Turning to FIG. 12, a process 1200 for generating a resolution solution is provided according to some embodiments. As used herein, the resolution solution may be referred to as a “bridging” solution. The bridging solution is generated for each violation/scenario. While the process describes simulated bridging solutions of: optimization of DERs, operation enhancements, infrastructure enhancements, and load curtailment, other suitable bridging solutions may be used.

Initially, at S1210, the critical scenarios are received at the bridging solutions tool 318. As described above, pursuant to some embodiments, the physics-based power flow is not executed, and all of the critical scenarios included in the shortened list are received by the bridging solutions tool 318. In a case the critical scenarios are verified, the critical scenarios that are outside the acceptable threshold are received at the bridging solutions tool 318. The received critical scenarios may be less than all of the scenarios included in the shortened list. As a non-exhaustive example, the shortened list may include ten critical dates, and of those ten critical dates, the physics-based power flow determines that while all ten critical dates have violations, only eight of those scenarios have violations that exceed (are outside of) the user-defined threshold. In this example, only those eight scenarios are received by the bridging solutions tool 318. As another non-exhaustive example, in a case none of the ten scenarios exceed the user-defined threshold, the resolution solution process 1200 is not executed, and the results summarized with the approval of requested load interconnection and transmitted to a remote device. At S1212, an optimal power flow analysis is executed for the received critical scenarios with optimization of any distributed energy resources (DERs), such that at least one of the control logic and set points are changed for one or more DERs. The power flow analysis is a numerical, steady-state simulation technique to calculate how power flows through the grid, and in some cases at each bus (node) in the system. With the optimal power flow analysis, DER dispatches are optimized such that the equipment ratings violation and the voltage violations can be minimized. Pursuant to some embodiments, the power analysis may be executed by solving a Graphics Processing Units (GPUs)-accelerated AC Optimal Power Flow (ACOPF) for the critical scenarios to evaluate DER operations as a solution to resolve the grid violation significantly faster. The ACOPF may be run with a minimum violation objective and with a Conservation Voltage Reduction (CVR) objective (e.g., lower the voltage at the distribution level to the lower band of the acceptable range). The GPU-accelerated ACOPF may parallelize calculations for thousands of grid components simultaneously—using methods like Alternating Direction Method of Multipliers (ADMM) that decompose the problem into smaller, manageable pieces for solving by the GPU—to achieve near real-time performance for large-scale power systems.

At S1214, it is determined whether the violations are resolved for all critical scenarios in the shortened pruned list by optimizing DERs. The violations are resolved in a case that simulating the optimization of the DERs results in the violations being below the threshold. In a case optimizing the DERs would resolve the violation at S1214, optimizing DERs is recommended, and the process proceeds to S1216. In a case optimizing the DERs would not resolve the violation at S1214, the process proceeds to S1218. As a non-exhaustive example, if there are ten critical scenarios and after optimizing the DERs there still exist five critical scenarios with violations greater than the given threshold, the analysis indicates optimizing the DERs would not resolve the violation because there still exist five critical scenarios.

At S1216, optimizing the DERs recommendation is verified using a solution verification logic. Solution verification logic may analyze the recommendation automatically with respect to rules and/or via a human-in-the-loop analysis. In a case the recommendation is verified, the process proceeds to S1217 and a summary (e.g., 800) is generated. In a case the recommendation is not verified, the process proceeds to S1218.

At S1218 a simulation for operation enhancements is executed. This step may be optional, as indicated by the dotted line in FIG. 12. Operation enhancements include, but are not limited to, load roll/circuit reconfiguration with Advanced Distribution Management System Automatic Feeder Reconfiguration (ADMS AFR). Continuing with the non-exhaustive example, the simulation is executed for the five critical scenarios that remain unresolved after S1214.

ADMS is a software platform used to monitor, control, and optimize the entire distribution network. It integrates several systems, including, but not limited to, a Supervisory Control and Data Acquisition (SCADA) system (e.g., for real-time monitoring and control of field devices), an Outage Management System (OMS) (e.g., to detect, manage and restore power outages), and a Distribution Management System (DMS) (e.g., for network simulation, optimization and analysis). Generally, the AFR is an advanced application within the ADMS framework that, when a fault is detected (e.g., a downed line), automatically calculates and initiates the switching needed to isolate the faulted section and maintain uninterrupted power supply to as many customers as possible. Here, the ADMS AFR may generate a simulation with operation enhancements with switching (e.g., circuit reconfiguration and/or load roll (e.g. rotating power interruptions through different areas).

At 1220 it is determined whether the violations are resolved for all critical scenarios in the shortened pruned list by operation enhancements.

In a case, the operation enhancements with switching would resolve the violation at S1220, operation enhancements with switching are recommended, and the process proceeds to S1222. In a case, operation enhancements with switching would not resolve the violation at S1220, the process proceeds to S1224.

At S1222, the recommendation for operation enhancements with switching is verified using the solution verification logic, as described above at S1216. In a case the recommendation is verified, the process proceeds to S1217 and a summary is generated. In a case the recommendation is not verified, the process proceeds to S1224.

At S1224 a simulation for infrastructure enhancements (e.g., mobile substation, mobile storage (e.g. battery), etc.) being added to the network is executed. Infrastructure enhancements may be referred to as relocatable energy storage (RESS). A system may have a maximum number of RESS (N) that may be included in the network. In some instances, mobile storage units/substations are already deployed in the network (k).

At 1226 it is determined whether there are available RESS to add to the system (e.g., N—k is greater than or equal to 1).

In a case there are available RESS, the process proceeds to S1228 and a simulation is executed with: the RESS being added at the load interconnection site (and now k=k+1), all existing DERs and RESS are set to be optimizable and the ACOPF is executed with a minimum violation objective.

It is then determined at S1230 whether the violations are resolved for all critical scenarios in the shortened list by infrastructure enhancements.

In a case the infrastructure enhancements with added RESS would resolve the violation at S1230, adding RESS is recommended, and the process proceeds to S1232. In a case the violations are unresolved with infrastructure enhancements at S1230, the process returns to S1226 and it is determined whether there is another available RESS to add to the system (e.g., so total added would be k+2).

At 1232, the recommendation for infrastructure enhancements with added RESS is verified using solution verification logic, as described above at S1216. In a case the recommendation is verified, the process proceeds to S1217 and a summary is generated. In a case the recommendation is not verified, the process proceeds to S1234.

In a case it is determined at S1226 there are no available RESS to add to the system, the process proceeds to S1234. At S1234, the requested load is reduced (load curtailment) by changing a Load Curtailment Management System (LCMS) limit, all existing DERs and RESS are set to be optimizable, and the ACOPF is executed with the curtailed/reduced load. The load reduction may be for a peak day profile, for example or at days of non-peak load.

It is then determined at S1236 whether the violations are resolved for all critical scenarios in the shortened list by load curtailment.

In a case the load curtailment would resolve the violation at S1236, and the process proceeds to S1238. At S1238, the recommendation for load curtailment is verified using solution verification logic, as described above at S1216. In a case the recommendation is verified, the process proceeds to S1217 and a summary is generated with a recommendation to accept the request (accept status). In a case the recommendation is not verified or the violations are not resolved via load curtailment at S1236, the process proceeds to S1217 and a summary is generated with a recommendation to deny the request (reject status).

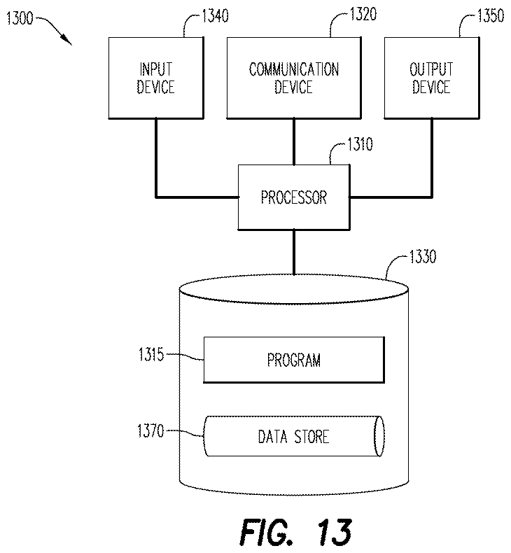

The embodiments described herein may be implemented using any number of different hardware configurations. For example, FIG. 13 illustrates an apparatus 1300 that may be, for example, associated with system 300 described with respect to FIG. 3. The apparatus 1300 comprises a processor 1310, such as one or more commercially available Central Processing Units (“CPUs”) in the form of one-chip microprocessors, coupled to a communication device 1320 configured to communicate via a communication network (not shown in FIG. 13). The communication device 1320 may be used to communicate, for example, with one or more remote third-party platforms, administrator computers, and/or communication devices (e.g., PCs and smartphones). Note that communications exchanged via the communication device 1320 may utilize security features, such as those between a public internet user and an internal network of an enterprise. The security features might be associated with, for example, web servers, firewalls, and/or PCI infrastructure. The apparatus 1300 further includes an input device 1340 (e.g., a mouse and/or keyboard to receive a load interconnection request, etc.) and an output device 1350 (e.g., to output a summary, etc.).

The processor 1310 also communicates with a storage device 1330. The storage device 1330 may comprise any appropriate information storage device, including combinations of magnetic storage devices (e.g., a hard disk drive), optical storage devices, mobile telephones, and/or semiconductor memory devices. The storage device 1330 stores a program 1315 and/or an application for controlling the processor 1310. The processor 1310 performs instructions of the program 1315, and thereby operates in accordance with any of the embodiments described herein. For example, the processor 1310 may receive a request for a load interconnection and executes the ML model and the bridging solution.

The program 1315 may be stored in a compressed, uncompiled and/or encrypted format. The program 1315 may furthermore include other program elements, such as an operating system, a database management system, and/or device drivers used by the processor 1310 to interface with peripheral devices.

As used herein, information may be “received” by or “transmitted” to, for example: (i) the apparatus 1300 from another device; or (ii) a software application or module within the apparatus 1300 from another software application, module, or any other source.

In some embodiments (such as shown in FIG. 13), the storage device 1330 further includes a data store 1370. It is noted that various databases might be split or combined in accordance with any of the embodiments described herein. For example, the data store 1370 might be combined and/or linked with another database within the program 1315.

The following illustrates various additional embodiments of the invention. These do not constitute a definition of all possible embodiments, and those skilled in the art will understand that the present invention is applicable to many other embodiments. Further, although the following embodiments are briefly described for clarity, those skilled in the art will understand how to make any changes, if necessary, to the above-described apparatus and methods to accommodate these and other embodiments and applications.

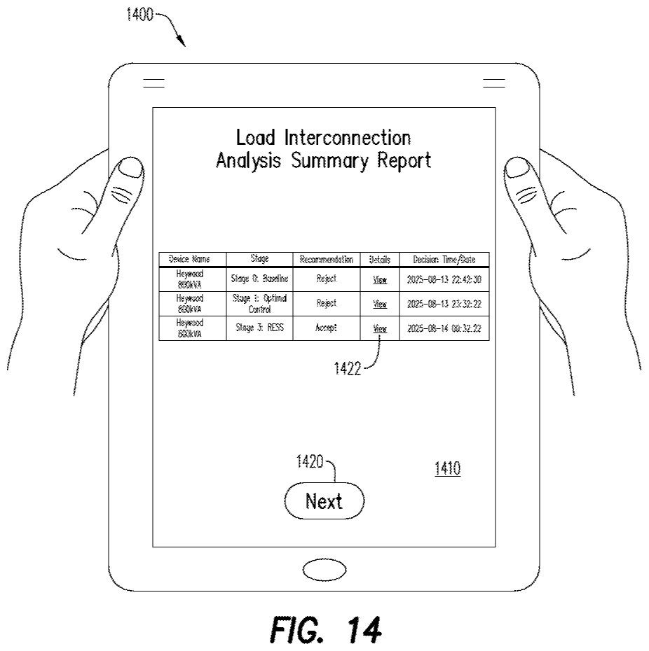

Although specific hardware and data configurations have been described herein, note that any number of other configurations may be provided in accordance with embodiments of the present invention (e.g., the databases described herein may be combined or stored in external systems). Moreover, although embodiments have been described with respect to specific types of entities, embodiments may instead be associated with other types of enterprises in addition to and/or instead of those described herein. Similarly, the displays and devices illustrated herein are only provided as examples, and embodiments may be associated with any other types of user interfaces. For example, FIG. 14 illustrates a tablet computer 1400 with a Load Interconnection Analysis Summary Report display 1410 including a summary report, according to some embodiments. Selection of the “Next” icon 1420 might result in transmission of the report to another party. Selection of a “View” link 1422 may display additional information.

The present invention has been described in terms of several embodiments solely for the purpose of illustration. Persons skilled in the art will recognize from this description that the invention is not limited to the embodiments described but may be practiced with modifications and alterations limited only by the spirit and score of the appended claims.

What is claimed is:

1. A system comprising:
a memory storing processor-executable program code: and
a processing unit to execute the processor-executable program code to cause the system to:
receive a load interconnection request including a load profile;
generate load forecast values;
generate, using a machine learning (“ML”) model, a pruned list of load scenarios based on the generated load forecast values, wherein each load scenario included in the pruned list includes at least one grid violation;
generate a resolution plan for overcoming each grid violation, wherein the resolution plan is based on simulated solutions; and
generate a load interconnection summary report including the generated resolution plan for the pruned list of load scenarios.

2. The system of claim 1, wherein generation of the pruned list of load scenarios further comprises program code to cause the system to:
generate a plurality of scenarios, wherein each load scenario is generated for each time period during a pre-determined duration, the load scenario including at least one predicted grid violation;
create one or more clusters, each cluster including one or more load scenarios;
select a representative load scenario from each cluster; and
generate the pruned list including the representative load scenarios.

3. The system of claim 2, further comprising processor-executable program code to cause the system to:
verify, by a physics-based model, each load scenario in the pruned list of load scenarios.

4. The system of claim 1, wherein generation of the load forecast values further comprises program code to cause the system to:
receive load and generation data from at least one of an external data source and a simulated data source; and
generate load forecast values based on the received load and generation data, weather input, historical data, social factors and technology.

5. The system of claim 1, wherein the grid violation is at least one of a current violation, a voltage violation, and power flow violations.

6. The system of claim 1, wherein generation of the resolution plan further comprises processor-executable program code to cause the system to:
receive the pruned list of load scenarios;
generate a bridging solution to resolve the violations included in the pruned list of load scenarios;
execute a bridging solution simulation of the bridging solution; and
determine the executed bridging solution simulation resolves the violations or does not resolve the violations.

7. The system of claim 6, further comprising processor-executable program code to cause the system to:
generate the load interconnection summary report in a case an output of the executed bridging solution simulation resolves the violations.

8. The system of claim 6, further comprising processor-executable program code to cause the system to:
generate another bridging solution to resolve the violations included in the pruned list of load scenarios in a case the output of the executed bridging solution simulation does not resolve the violations.

9. The system of claim 6, wherein the bridging solution simulation further comprises processor-executable program code to cause the system to:
set all existing distributed energy resources (DER) in a network to an optimized level;
execute an AC optimal power flow (ACOPF) with a minimum violation objective; and
determine a violation resolution status for all load scenarios in the pruned list of load scenarios.

10. The system of claim 9, wherein setting all existing distributed energy resources (DER) in the network to the optimized level further comprises program code to:
change at least one of control logic and set points for one or more DERs.

11. The system of claim 8, wherein another bridging solution simulation further comprises processor-executable program code to cause the system to:
provide infrastructure enhancements by adding at least one of: at least one mobile substation and at least one mobile storage device; and
determine a violation resolution status for all load scenarios in the pruned list of load scenarios.

12. The system of claim 8, wherein another bridging solution simulation further comprises processor-executable program code to cause the system to:
curtail load usage during pre-defined time periods; and
determine a violation resolution status for all load scenarios in the pruned list of load scenarios.

13. The system of claim 1, wherein the load interconnection request includes a maximum load, a location, a date of energization request, a user type, and a representative load profile.

14. A method comprising:
receiving a load interconnection request including a load profile;
generating load forecast values;
generating, using a machine learning (“ML”) model, a pruned list of load scenarios based on the generated load forecast values, wherein each load scenario included in the pruned list includes at least one grid violation of a current violation or a voltage violation;
generating a resolution plan for overcoming each grid violation, the resolution plan based on simulated solutions; and
generating a load interconnection summary report including the generated resolution plan for the pruned list of load scenarios.

15. The method of claim 14, wherein generation of the pruned list of load scenarios further comprises:
generating a plurality of scenarios, wherein each load scenario is generated for each time period during a pre-determined duration, the load scenario including at least one predicted grid violation;
creating one or more clusters, each cluster including one or more load scenarios;
selecting a representative load scenario from each cluster; and
generating the pruned list including the representative load scenarios.

16. The method of claim 15, further comprising:
verifying, by a physics-based model, each load scenario in the pruned list of load scenarios.

17. The method of claim 14, wherein generation of the resolution plan further comprises:
receiving the pruned list of load scenarios;
generating a bridging solution to resolve the violations included in the pruned list of load scenarios;
executing a bridging solution simulation of the bridging solution; and
determining the executed bridging solution simulation resolves the violations or does not resolve the violations.

18. A non-transitory computer-readable storage medium comprising instructions which when computed by a processor cause a computer to perform a method comprising:
receiving a load interconnection request including a load profile;
generating load forecast values;
generating, using a machine learning (“ML”) model, a pruned list of load scenarios based on the generated load forecast values, wherein each load scenario included in the pruned list includes at least one grid violation of a current violation or a voltage violation;
generating a resolution plan for overcoming each grid violation, the resolution plan based on simulated solutions; and
generating a load interconnection summary report including the generated resolution plan for the pruned list of load scenarios.

19. The medium of claim 18, wherein generation of the pruned list of load scenarios further comprises:
generating a plurality of scenarios, wherein each load scenario is generated for each time period during a pre-determined duration, the load scenario including at least one predicted grid violation;
creating one or more clusters, each cluster including one or more load scenarios;
selecting a representative load scenario from each cluster; and
generating the pruned list including the representative load scenarios.

20. The medium of claim 18, wherein generation of the resolution plan further comprises:
receiving the pruned list of load scenarios;
generating a bridging solution to resolve the violations included in the pruned list of load scenarios;
executing a bridging solution simulation of the bridging solution; and
determining the executed bridging solution simulation resolves the violations or does not resolve the violations.
